(19) United States
(12) Patent Application Publication
(10) Pub. No.: US 2026/0009123 A1
(43) Pub. Date: Jan. 8, 2026

(54) VAPORIZER AND ION SOURCE

(71) Applicant: NISSIN ION EQUIPMENT CO., LTD., Koka-city (JP)

(72) Inventor: Shinkichi HAMADA, Koka-city (JP)

(73) Assignee: NISSIN ION EQUIPMENT CO., LTD., Koka-city (JP)

(21) Appl. No.: 19/256,311

(22) Filed: Jul. 1, 2025

(30) Foreign Application Priority Data
Jul. 8, 2024 (JP) 2024-109450

(51) Int. Cl. C23C 14/48; C23C 14/24

(52) U.S. Cl. CPC C23C 14/48; C23C 14/243

(57) ABSTRACT

A vaporizer for generating a vapor from a reaction product of a solid material and a chlorine-containing gas includes a crucible, and a heater that heats the crucible. The crucible includes a first portion into which the chlorine-containing gas is introduced, a second portion including a nozzle made of carbon for discharging the vapor from the crucible, and a third portion which receives the solid material. The nozzle includes a first surface that forms a side wall of the crucible, and includes a protrusion that protrudes from the first surface toward the third portion.

### CROSS REFERENCE TO RELATED APPLICATIONS

This application is based on and claims priority from Japanese Patent Application No. JP2024-109450 filed on Jul. 8, 2024 in the Japan Patent Office, the contents of which being incorporated by reference herein in its entirety.

### BACKGROUND

### 1. Field

The present disclosure relates to a vaporizer and an ion source having the vaporizer.

### 2. Description of Related Art

Silicon carbide (SiC) devices are expected to be used in high-voltage and high-temperature applications such as electric vehicles, railways and power plants, and are featured as one of the items to realize a low-carbon society. The manufacturing process for SiC devices is similar to that of silicon devices in that both use an ion implantation process.

In the ion implantation process for SiC devices, nitrogen or phosphorus ions are implanted as an N-type dopant and aluminum or boron ions are implanted as a P-type dopant into a SiC wafer in the production of a PN junction.

### SUMMARY

According to an aspect of one or more embodiments, there is provided a vaporizer for generating a vapor from a reaction product of a solid material and a chlorine-containing gas, the vaporizer comprising a crucible; and a heater configured to heat the crucible. The crucible comprises a first portion into which the chlorine-containing gas is introduced; a second portion including a nozzle made of carbon for discharging the vapor from the crucible; and a third portion which is configured to receive the solid material. The nozzle comprises a first surface that forms a side wall of the crucible, and includes a protrusion that protrudes from the first surface toward the third portion.

According to another aspect of one or more embodiments, there is provided an ion source comprising the vaporizer described above; a plasma generation chamber in fluid communication with the vaporizer and in which plasma is generated from the vapor supplied from the vaporizer; and an extraction electrode configured to extract an ion beam from the plasma.

According to another aspect of one or more embodiments, there is provided a vaporizer comprising a crucible configured to receive a solid material, the crucible comprising an inlet at a proximal end of the crucible for receiving a chlorine-containing gas and a nozzle at a distal end of the crucible; and a heater configured to heat the crucible. The nozzle may be made of carbon and may comprise a surface that forms a side wall of the distal end of the crucible and a protrusion having a distal end that protrudes from the surface into the crucible

### BRIEF DESCRIPTION OF THE DRAWINGS

The above and/or other aspects will become apparent and more readily appreciated from the following description of various embodiments, taken in conjunction with the accompanying drawings, in which:

FIG. 1 illustrates an example of an ion source according to some embodiments;

FIG. 2 illustrates an example of an enlarged view of a first nozzle of the ion source of FIG. 1, according to some embodiments;

FIG. 3 illustrates an example of a cross-sectional view of a first nozzle of FIG. 2, according to some embodiments;

FIG. 4 illustrates an example of a cross-sectional view of a first nozzle of FIG. 2, according to some embodiments;

FIG. 5 illustrates an example of a cross-sectional view of a first nozzle of FIG. 2, according to some embodiments;

FIG. 6 illustrates an example of a cross-sectional view of a first nozzle of FIG. 2, according to some embodiments; and

FIG. 7 illustrates an example of a cross-sectional view of a first nozzle of FIG. 2, according to some embodiments.

### DETAILED DESCRIPTION

In all the drawings for explaining the various embodiments, common components are denoted by the same reference numerals, and repeated description thereof will be omitted for conciseness. The following embodiments do not unduly limit the contents of the present disclosure described in the appended claims. Further, all the components shown in the embodiments are not necessarily essential components of the present disclosure. Each drawing is a schematic view and is not necessarily intended to illustrate various dimensions strictly.

In the generation of nitrogen ions, phosphorus ions, and boron ions, a plasma is generally generated using a gas as a raw material. However, there is no optimum gas as a raw material to produce aluminum ions.

Sputtering of aluminum-containing solid materials (such as aluminum nitride, alumina, etc.) has been used to generate the plasma containing aluminum ions. Further, a method using a vaporizer is also used. Specifically, a solid material containing aluminum is placed in a crucible, and the crucible is heated to generate a vapor containing aluminum from the solid material. The plasma containing aluminum ions is generated from the generated vapor.

In contrast to such a related art vaporizer, a new vaporizer has been proposed, and is described in U.S. patent application Ser. No. 17/714,491, filed Apr. 6, 2022, now U.S. Pat. No. 12,112,915 for “VAPORIZER, ION SOURCE AND METHOD FOR GENERATING ALUMINUM-CONTAINING VAPOR” and/or U.S. patent application Ser. No. 18/948,063, filed Nov. 14, 2024, published as U.S. Patent Application Publication No. 2025/0071881 for “VAPORIZER, ION SOURCE AND METHOD FOR GENERATING ALUMINUM-CONTAINING VAPOR” and/or U.S. patent application Ser. No. 17/945,705, filed Sep. 15, 2022, published as U.S. Patent Application Publication No. 2024/0098869 for “VAPORIZER, ION SOURCE AND METHOD FOR GENERATING ALUMINIUM-CONTAINING VAPOR”, the entire contents of each of these U.S. patent applications being herein incorporated by reference in their entireties.

In the new vaporizer, a reactive gas (e.g., chlorine gas, hydrogen chloride gas, or the like) is supplied to a crucible. A solid material (e.g., pure aluminum, aluminum nitride, alumina, etc.) is placed in the crucible. In the crucible, a reactive gas reacts with the solid material to produce a reaction product (e.g., aluminum chloride) on the solid material. The reaction product is vaporized by heating the crucible, and the vaporized reaction product is supplied to a plasma generation chamber. In the plasma generation chamber, a plasma containing aluminum ions is generated based on the supplied vapor.

In order to improve an efficiency of aluminum ion generation, it is advantageous to increase the crucible temperature. When the crucible temperature is increased, the amount of chlorine radicals generated due to a chlorine component in the reactive gas increases. Chlorine radicals readily bond with aluminum. As a result, the amount of AlCl produced increases.

A long cylindrical crucible for a large solid material is advantageous to increase a lifetime of the vaporizer. In such a long crucible, a temperature distribution exists in the longitudinal direction of the crucible. The temperature distribution tends to be such that the temperature is higher at a center of the crucible where a heater is disposed, and the temperature is lower at the end of the crucible than at the center of the crucible.

When AlCl that is produced in the central portion of the crucible at a relatively high temperature reaches the end portion of the crucible at a relatively low temperature by a flow of the reactive gas supplied into the crucible in the longitudinal direction of the crucible, AlCl is separated into Al and Cl due to the influence of the temperature difference.

The crucible and a nozzle fixed to the end of the crucible are made of a carbon material in terms of heat resistance, processability, cost, and the like.

When AlCl is separated, Cl is discharged as a gas. By contrast, the separated Al remains in the crucible end portion in an active state, and the separated Al reacts with the crucible and the nozzle, which as discussed above, is made of a carbon material, to generate Al₄C₃.

In the crucible heated to a high temperature, aluminum is liquefied. The wettability of the liquefied aluminum is improved by mixing Al₄C₃ in the liquefied aluminum.

When the wettability of the liquefied aluminum is improved, there may be a disadvantage that melted aluminum creeps up to the inlet of the nozzle that discharges the vapor into the plasma generation chamber, and causes clogging of the nozzle. Various embodiments may address these disadvantages.

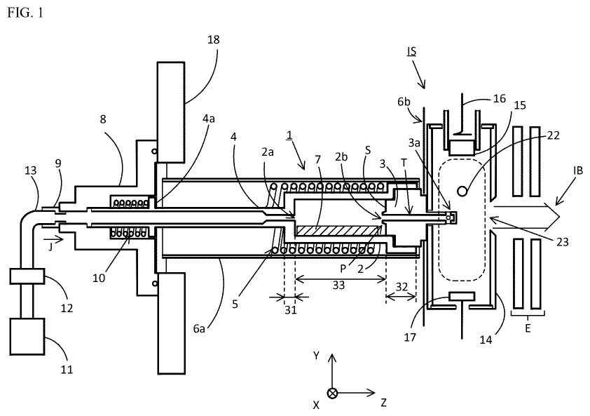

FIG. 1 is a schematic cross-sectional view of an ion source IS, according to an embodiment. In an embodiment, the ion source IS may be an indirectly heated cathode (IHC) ion source. In an embodiment, the ion source IS may include a plasma generation chamber 14, a cathode 15, a filament 16, and a repeller electrode 17. In the ion source IS, the filament 16 heats the cathode 15. The heated cathode 15 emits ionizing electrons into the plasma generation chamber 14. The repeller electrode 17 is disposed opposite to the cathode 15. The repeller electrode 17 repels the ionizing electrons approaching the repeller electrode 17 toward the cathode 15.

An electromagnet (not shown) may be disposed outside the plasma generation chamber 14. The electromagnet generates a magnetic field along the direction in which the cathode 15 and the repeller electrode 17 face each other inside the plasma generation chamber 14.

A vapor containing aluminum is supplied from a vaporizer 1 to the plasma generation chamber 14. In the plasma generation chamber 14, a plasma (indicated by the broken line) is generated from the vapor. An ion beam IB containing aluminum ions is extracted from an ion extraction port 23 of the plasma generation chamber 14 by an extraction electrode E.

FIG. 1 shows an example of the extraction electrodes E having two electrodes. Each electrode has a passage hole for the ion beam IB. However, the number of electrodes constituting the extraction electrode E shown in FIG. 1 is merely an example. In some embodiments, the number of electrodes constituting the extraction electrode E may be three or more, and may be changed according to a configuration of the ion source.

The vaporizer 1 includes a crucible 2 configured to receive with an aluminum-containing solid material 7 (for example, pure aluminum, aluminum nitride, or aluminum oxide), a first nozzle 3, a second nozzle 4, and a heater 5. The solid material 7 may include a powder.

The crucible 2 illustrated in FIG. 1 may be a cylindrical member elongated in one direction. For example, the axis of the crucible 2 may extend along a Z-axis direction, as illustrated in FIG. 1. In the Z-axis direction, the crucible 2 has a first portion 31 at a proximal end thereof, a second portion 32 at a distal end thereof, and a third portion 33 between the first portion 31 and the second portion 32.

The solid material 7 is received in the third portion 33. In the second portion 32 (i.e., at the distal end of the crucible 2), an outlet 2b for supplying the vapor from the crucible 2 to the plasma generation chamber 14 is provided. In the first portion 31 (i.e., at the proximal end of the crucible 2), an inlet 2a for receiving a chlorine-containing gas as a reactive gas into the crucible 2 is provided.

In an embodiment, the chlorine-containing gas may be a gas containing a chloride ingredient such as a chloride gas (Cl₂) or a hydrochloride gas (HCl).

The first nozzle 3 may be detachably attached to the crucible 2. In an embodiment, as illustrated in FIG. 1, the second nozzle 4 for supplying the reactive gas into the crucible 2 may be formed integrally with the crucible 2. As a method of attaching the first nozzle 3 to the crucible 2, various methods (for example, fitting and/or screwing) can be used.

In an embodiment, the first nozzle 3, the second nozzle 4, and the crucible 2 may be made of a carbon material in terms of heat resistance, processability, cost, and the like.

In FIG. 1, an arrow J indicates the flow of the chlorine-containing gas supplied to the crucible 2. The chlorine-containing gas flows from a gas supply source 11 through a valve 12 in a pipe 13, the second nozzle 4, the crucible 2, and the first nozzle 3 in this order, and flows into the plasma generation chamber 14.

When the chlorine-containing gas flows into the crucible 2, the chlorine-containing gas reacts with the aluminum-containing solid material 7 heated to a high temperature. This reaction produces a reaction product such as aluminum chloride (AlCl₃).

The reaction product thus produced is vaporized in the crucible 2 at a high temperature, whereby the vapor containing aluminum particles are produced. The vapor and the chlorine-containing gas are supplied from the crucible 2 to the plasma generation chamber 14 through the first nozzle 3.

In some embodiments, the aluminum-containing solid material 7 may be pure aluminum with a purity of 99.90% or more. Pure aluminum increases the proportion of aluminum in the vapor relative to other materials. By using such pure aluminum, the ion beam current of the ion beam IB containing aluminum ions extracted from the ion source IS increases.

However, the aluminum-containing solid material 7 is not limited to pure aluminum. In some embodiments, aluminum nitride, aluminum oxide, and/or other aluminum-containing solid materials may be used.

The chlorine-containing gas may be supplied to the second nozzle 4 through a connection member 9 fitted into the second nozzle 4. Further, a mass flow controller may be connected to the pipe 13 connecting the gas supply source 11 and the connection member 9 to control the flow rate of the chlorine-containing gas. However, a specific configuration for supplying the gas is not particularly limited as long as the chlorine-containing gas can be supplied to the connection member 9.

In an embodiment, the first nozzle 3 may include an end 3a opposite to an end of the first nozzle 3 that is attached to the crucible 2. In an embodiment, the end 3a may protrude into the plasma generation chamber 14. The end 3a is provided with vapor supply holes in four directions orthogonal to each other. With this configuration, the vapor can be diffused and supplied in multiple directions inside the plasma generation chamber 14. However, the number of the vapor supply holes formed in the end 3a is not limited to four. In some embodiments, the number of vapor supply holes may be less than four or more than four.

The heater 5 may be disposed on the outer periphery of the crucible 2. The heater 5 may be, for example, a coil heater or a sheet heater. However, various heaters other than a coil heater or a sheet heater may be used. In an embodiment, a first heat shield plate 6a for blocking heat radiation from the heater 5 may be disposed on the outer periphery of the heater 5. Similarly, in an embodiment, in order to avoid heat transmission from the plasma generation chamber 14 to the crucible 2, a second heat shield plate 6b may be disposed between the plasma generation chamber 14 and the first nozzle 3.

The second nozzle 4 may have a large-diameter portion 4a. A flange 8 may be provided for attaching the vaporizer 1 to an ion source flange 18.

In FIG. 1, the ion source flange 18 indirectly supports the plasma generation chamber 14 and other components such as the filament 16 and the cathode 15 around the plasma generation chamber 14 by supporting components (not shown).

In some embodiment, a coil spring 10 may be provided between the flange 8 and the large-diameter portion 4a of the second nozzle 4. The coil spring 10 may be an elastic member that biases the vaporizer 1 against the side wall of the plasma generation chamber 14 and keeps the space between the first nozzle 3 and the plasma generation chamber 14 airtight, in order to prevent the inflow of the vapor and/or the chlorine-containing gas from between the members.

The elastic member for urging the vaporizer 1 against the side wall of the plasma generation chamber 14 is not limited to the coil spring 10, and in some embodiments, other elastic members such as a plate spring may be used.

In an embodiment, in order to keep the space between the first nozzle 3 and the plasma generation chamber 14 airtight, one or more gaskets (not shown) may be provided between the vaporizer 1 and the side wall of the plasma generation chamber 14.

In order to avoid excessive pressure due to the elastic force of the coil spring 10, a damper, for example, a spring clip in the form of a snap ring may be attached to the first nozzle 3. Similarly, in order to prevent an excessive force due to the elasticity of the coil spring 10, a damper (for example, a spring clip) may be provided between the large-diameter portion 4a of the second nozzle 4 and the first heat shield plate 6a.

In some embodiments, the aluminum-containing solid material 7 may have a semicircular cross section in an XY plane. Since the chlorine-containing gas flows along the surface of the aluminum-containing solid material 7, the chlorine-containing gas and the solid material 7 can be efficiently reacted.

Ion species other than aluminum ions may also be used to create PN junctions in SiC devices. When the other ion species are generated, a gas such as PH₃, PF₃, BF₃, or N₂ is supplied to the plasma generation chamber 14. In an embodiment, a supply path of such a gas may be shared with the flow path of the chlorine-containing gas.

However, since a disadvantage such as unexpected discharge may occur due to mixing with the residual gas, in some embodiments, a gas supply path for the other ion species may be separately provided from the flow path of the chlorine-containing gas.

In an embodiment, as illustrated in FIG. 1, a gas inlet 22 for supplying another gas species is provided in the wall surface of the plasma generation chamber 14 on the X-axis side.

The IHC ion source shown in FIG. 1 is an example. As the ion source, other configurations such as a Bernas type and a high-frequency type may be adopted.

Instead of projecting the end 3a of the first nozzle 3 into the plasma generation chamber 14, in some embodiments, the tip of the end 3a provided in the first nozzle 3 may be flush with the wall of the plasma generation chamber 14. In this case, the number of vapor supply holes formed in the end 3a of the first nozzle 3 may be one in the Z direction.

In some embodiments, the first nozzle 3 may be provided with a protrusion P at the end of the first nozzle 3 on the crucible 2 side. In an embodiment, a distal end of the protrusion P may extend into the crucible 2. By providing the protrusion P, the aluminum having improved wettability may be prevented from flowing into a passage T of the first nozzle 3.

As discussed above, in the crucible 2 heated to a high temperature, a large amount of chlorine radicals is generated from the chlorine-containing gas. Chlorine radicals readily combine with aluminum to form AlCl.

When AlCl that is produced at the center of the crucible 2 at a relatively high temperature reaches the end of the crucible at a relatively low temperature by the flow of the reactive gas supplied to the crucible 2 in the longitudinal direction of the crucible 2, AlCl is separated into Al and Cl due to the influence of the temperature difference.

When AlCl is separated, Cl is discharged as a gas. However, the separated Al remains at the end of the crucible 2 in an active state, and the separated Al reacts with the crucible 2, which is made of carbon, and the first nozzle 3 to produce Al₄C₃.

In the crucible 2 heated to a high temperature, aluminum is liquefied. The Al₄C₃ mixed in the aluminum improves the wettability of the liquefied aluminum. The aluminum with improved wettability travels through the crucible and reaches the vicinity of the first nozzle 3.

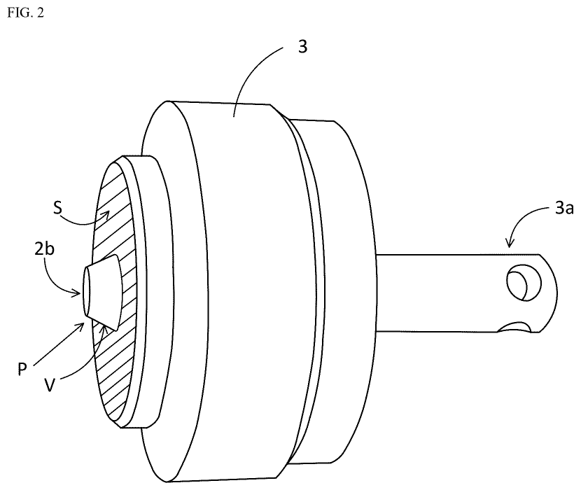

FIG. 2 is an enlarged view of the first nozzle 3 shown in FIG. 1, according to an embodiment. The aluminum with improved wettability may adhere to a first surface S of the first nozzle 3 in FIG. 2. The first surface S forms a side wall of the crucible 2 on the side of the plasma generation chamber 14. The amount of aluminum deposited on the first surface S increases with time, and when the first surface S is a flat surface and does not include the protrusion P, after a certain amount of time, the aluminum may flow into the passage T of the first nozzle 3. As a result, clogging of the first nozzle 3 may be caused.

However, as shown in FIGS. 1 and 2, by providing the protrusion P on the first surface S of the first nozzle 3 that forms the side wall of the crucible 2, it is possible to suppress the inflow of aluminum into the passage T. This suppression improves the lifetime of the vaporizer 1. In an embodiment, the protrusion P may be a tapered portion V of the first nozzle 3 that protrudes from the first surface S to the third portion 33 side of the crucible 2. For example, in some embodiments, the protrusion P may have a slope that intersects the first surface S. The protrusion P may include a portion of the passage T.

There may be a disadvantage that the aluminum that has flowed into the passage T will flow into the plasma generation chamber 14 due to the flow of the reactive gas. Conductive parts having different potentials are disposed in the plasma generation chamber 14. When aluminum flows into the plasma generation chamber 14, there may be a concern that the conductive parts may be short-circuited.

However, by providing the protrusion P on the first surface S of the first nozzle 3 forming the side wall of the crucible 2, it is possible to suppress the inflow of aluminum into the passage T, and thus it is possible to alleviate such a disadvantage.

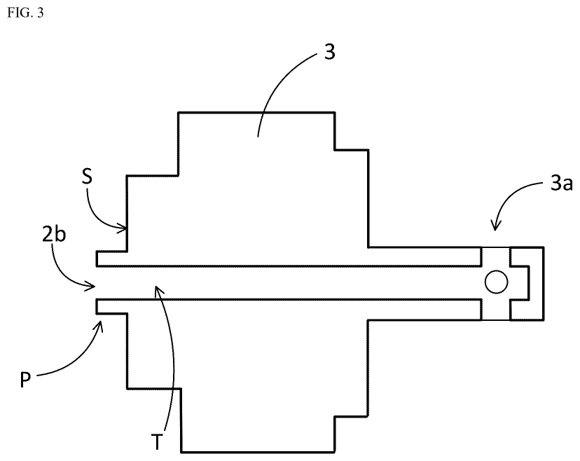

FIG. 3 illustrates an example of a cross-sectional view of the first nozzle 3, according to some embodiments. The protrusion P in FIGS. 1 and 2 has a shape in which the top of a cone is cut, but in some embodiment, the protrusion P may have a columnar shape as in the protrusion P illustrated in FIG. 3. Even when the protrusion P shown in FIG. 3 is employed, the lifetime of the vaporizer 1 can be improved as in the case of the protrusion P shown in FIGS. 1 and 2.

However, in order to enlarge an internal space of the crucible 2 and enhance the effect of suppressing the inflow of aluminum into the passage T, the configuration shown in FIGS. 1 and 2 in which the protrusion P has the tapered portion V is advantageous.

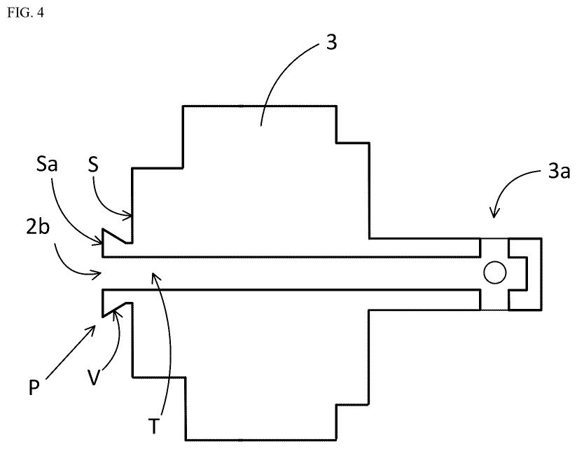

FIG. 4 illustrates an example of a cross-sectional view of the first nozzle 3, according to some embodiments. The tapered portion V may be tapered in different ways. For example, in some embodiments, the protrusion P may have the tapered portion V, as shown in FIG. 4. In FIG. 4, a diameter of the protrusion P is reduced toward the first surface S. For example, in some embodiments, the protrusion P may have a slope that intersects the first surface S. In some embodiments, the protrusion P may include a large diameter portion at an end portion at a distal end thereof, and a diameter of the large diameter portion may be larger than a diameter of the protrusion P at the first surface S.

If the protrusion P protrudes toward the center inside the crucible 2, the temperature of the end surface Sa of the protrusion P is sufficiently higher than the temperature of the first surface S. If the end surface Sa of the protrusion P can be maintained at a high temperature, the formation of a Al₄C₃ on the end surface Sa is suppressed, and thus the wettability of aluminum on the end surface Sa is low. Thus, even if liquefied aluminum adheres to the end surface Sa of the protrusion P, the liquefied aluminum can be retained on the end surface Sa as long as aluminum does not excessively flow from the first surface S to the end surface Sa.

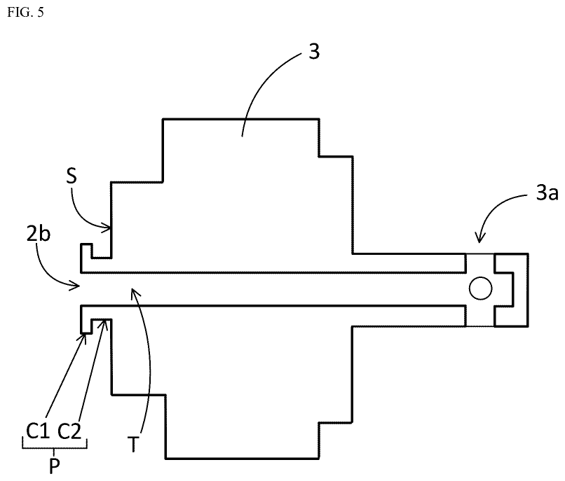

FIG. 5 illustrates an example of a cross-sectional view of the first nozzle 3, according to some embodiments. Similar to the configuration example of FIG. 4, in some embodiments, the protrusion P having a double cylindrical structure (a first cylindrical structure C1 and a second cylindrical structure C2) with different diameters shown in FIG. 5 may be employed. If the temperature at the first cylindrical structure C1 that has a large diameter is sufficiently higher than that at the first surface S, even if liquefied aluminum adheres to the end surface of the first cylindrical structure C1, the aluminum can be retained on the first cylindrical structure C1, as in the case of the end surface Sa described with reference to FIG. 4. In some embodiments, a diameter of the first cylindrical structure C1 may be larger than a diameter at the first surface S of the second cylindrical structure C2.

As shown in FIGS. 4 and 5, by providing the large-diameter structure having a large size at a position spaced apart from the first surface S, the large-diameter structure may serve as a barb, and it is possible to effectively suppress the inflow of aluminum having good wettability from the first surface S into the passage T.

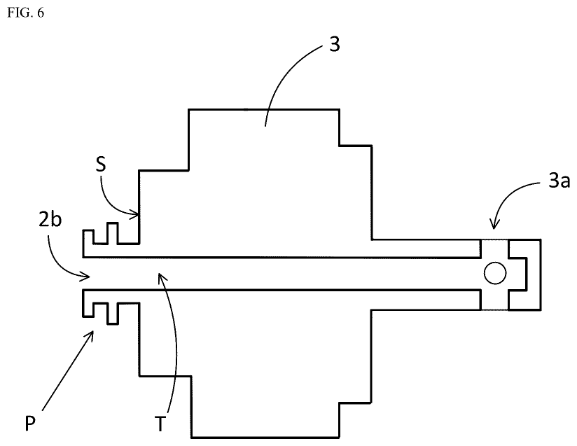

FIG. 6 illustrates an example of a cross-sectional view of the first nozzle 3, according to some embodiments. Similar to the configuration in which the large-diameter structure having a large dimension is provided at a position spaced apart from the first surface S, a configuration shown in FIG. 6 may be adopted. In an embodiment, as illustrated in FIG. 6, the protrusion P may include two large-diameter structures having different diameters. In an embodiment, the protrusion P may thus include three or more cylindrical structures having different diameters. For example, in an embodiment, a distal large-diameter structure and a proximal large-diameter structure may be provided that each extend in a radial direction and a connecting cylindrical structure, which has a smaller diameter that the distal large-diameter structure and the proximal large-diameter structure, may connect the distal large-diameter structure and the proximal large-diameter structure in an axial direction.

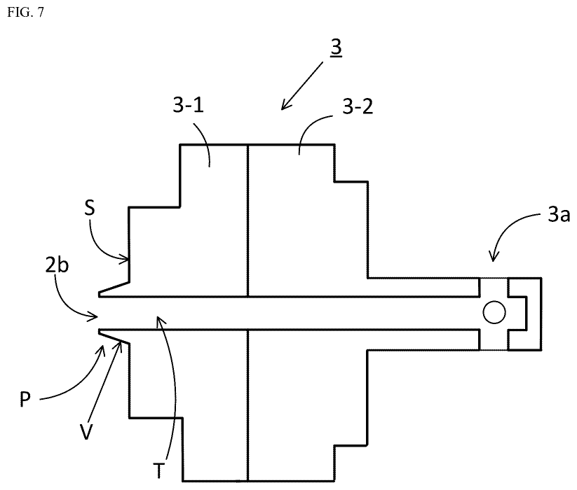

FIG. 7 illustrates an example of a cross-sectional view of the first nozzle 3, according to some embodiments. The first nozzle 3 shown in FIGS. 1 to 6 is formed of one member, but in some embodiments, the first nozzle 3 may be formed of a plurality of members as shown in FIG. 7.

In some embodiments, as illustrated in FIG. 7, the first nozzle 3 may include a first member 3-1 and a second member 3-2. The first member 3-1 and the second member 3-2 may be assembled by fitting, screwing, or the like. The configuration of the first member 3-1 may be the same as that of the embodiments described with respect to FIGS. 1-6. That is, the first member 3-1 forming a part of the first nozzle 3 may have the first surface S forming the side wall of the crucible 2, and the first surface S may have the protrusion P which projects toward the inside of the crucible 2 and in which the passage T for discharging the vapor is formed.

In the above embodiments, the material containing aluminum is described as an example of the solid material 7, but embodiments are not limited thereto. In some embodiments, the solid material 7 may contain other metals such as titanium, nickel, molybdenum, tungsten, etc., or may contain sulfur.

The other solid materials such as titanium, nickel, molybdenum, tungsten, etc., or may contain sulfur may be reacted with a chlorine-containing gas to produce a reaction product, and a vapor may be produced from the reaction product.

Even when the type of the solid material 7 is changed, there may be a disadvantage in that clogging of the nozzle as in the case of using the aluminum-containing solid material 7 may occur. However, by using the first nozzle 3 including the protrusion P, such a disadvantage can be addressed, and the lifetime of the vaporizer 1 can be extended.

It should be understood that embodiments are not limited to the various embodiments described above, but various other changes and modifications may be made therein without departing from the spirit and scope thereof as set forth in appended claims.

What is claimed is:

1. A vaporizer for generating a vapor from a reaction product of a solid material and a chlorine-containing gas, the vaporizer comprising:
a crucible; and
a heater configured to heat the crucible;
wherein the crucible comprises:
a first portion into which the chlorine-containing gas is introduced;
a second portion including a nozzle made of carbon for discharging the vapor from the crucible; and
a third portion which is configured to receive the solid material;
wherein the nozzle comprises a first surface that forms a side wall of the crucible, and includes a protrusion that protrudes from the first surface toward the third portion.

2. The vaporizer according to claim 1, wherein the first portion and the second portion face each other in a direction in which the chlorine-containing gas is introduced.

3. The vaporizer according to claim 1, wherein the nozzle comprises a passage for discharging the vapor from the crucible, and wherein a portion of the passage is formed in the protrusion.

4. The vaporizer according to claim 1, wherein the protrusion comprises a slope that intersects the first surface.

5. The vaporizer according to claim 1, wherein the protrusion comprises a tapered portion.

6. The vaporizer according to claim 5, wherein the tapered portion increases in size from the first surface toward the third portion.

7. The vaporizer according to claim 5, wherein the tapered portion increases in size from the third portion toward the first surface.

8. The vaporizer according to claim 1, wherein the protrusion comprises a large diameter portion at a distal end thereof, and wherein a diameter of the large diameter portion is larger than a diameter of the protrusion at the first surface.

9. The vaporizer according to claim 1, wherein the protrusion comprises three or more cylindrical structures having different diameters.

10. The vaporizer according to claim 1, wherein the protrusion comprises a first cylindrical structure and a second cylindrical structure that project in a radial direction and connecting structures that connect the first cylindrical structure and the second cylindrical structure in an axial direction.

11. The vaporizer according to claim 1, wherein the nozzle comprises four holes for releasing the vapor.

12. The vaporizer according to claim 11, wherein the four holes are formed at positions orthogonal to each other.

13. The vaporizer according to claim 1, wherein the solid material comprises aluminum.

14. The vaporizer according to claim 13, wherein the solid material is pure aluminum.

15. An ion source comprising:
the vaporizer according to claim 1;
a plasma generation chamber in fluid communication with the vaporizer and in which plasma is generated from the vapor supplied from the vaporizer; and
an extraction electrode configured to extract an ion beam from the plasma.

16. A vaporizer comprising:
a crucible configured to receive a solid material, the crucible comprising an inlet at a proximal end of the crucible for receiving a chlorine-containing gas and a nozzle at a distal end of the crucible; and
a heater configured to heat the crucible;
wherein the nozzle is made of carbon and comprises a surface that forms a side wall of the distal end of the crucible and a protrusion having a distal end that protrudes from the surface into the crucible.

17. The vaporizer according to claim 16, wherein the nozzle comprises a passage for discharging a vapor from the crucible, and a portion of the passage is formed in the protrusion.

18. The vaporizer according to claim 16, wherein the protrusion has a tapered shape.

19. The vaporizer according to claim 16, wherein the protrusion comprises a large diameter portion at the distal end of the protrusion, and a diameter of the large diameter portion is larger than a diameter of the protrusion at the surface.

20. The vaporizer according to claim 16, wherein the solid material comprises aluminum or pure aluminum.
